(19) United States
(12) Patent Application Publication
(10) Pub. No.: US 2026/0244840 A1
(43) Pub. Date: Aug. 20, 2026

(54) HETEROGENEOUS IN-PACKAGE PHOTONIC-ELECTRONIC COMMUNICATION PLATFORM

(71) Applicant: University of Florida Research Foundation, Incorporated, Gainesville, FL (US)

(72) Inventors: Volker J. Sorger, Gainesville, FL (US); Hangbo Yang, Gainesville, FL (US); Shweta Uttam Meshram, Gainesville, FL (US)

(21) Appl. No.: 19/539,496

(22) Filed: Feb. 13, 2026

Related U.S. Application Data
(60) Provisional application No. 63/760,392, filed on Feb. 19, 2025.

(51) Int. Cl. G06F 30/394; G06F 30/392; H04L 45/00; H04L 45/12

(52) U.S. Cl. CPC G06F 30/394; G06F 30/392; H04L 45/00; H04L 45/12

(57) ABSTRACT

A system comprising a plurality of processing cores configured on a chip, wherein a processing core of the plurality of processing cores comprises a plurality of optical transceivers; a plurality of optical through-silicon vias (OTSVs) configured to provide a plurality of vertical optical connections between the plurality of processing cores and a plurality of optical redistribution layers (ORDLs); and the plurality of ORDLs configured to provide a plurality of horizontal optical connections between the plurality of processing cores, wherein (i) the plurality of ORDLs comprises a plurality of layers with non-crossing routings, and (ii) one or more data packets are directed between the plurality of processing cores through the plurality of OTSVs and the plurality of ORDLs.

### CROSS REFERENCE TO RELATED APPLICATION

This application claims the priority of U.S. Provisional Application No. 63/760,392, entitled “HETEROGENEOUS IN-PACKAGE PHOTONIC-ELECTRONIC COMMUNICATION PLATFORM,” filed on Feb. 19, 2025, the disclosure of which is hereby incorporated by reference in its entirety.

### BACKGROUND

Rapid advancement of high-performance computing (HPC) and artificial intelligence (AI) applications, particularly in machine learning (ML) and deep learning (DL), has led to an exponential increase in the demand for high-bandwidth, low-latency, and energy-efficient communication between processing cores on a chip. The capabilities of traditional electrical interconnects struggle to keep pace with such demands due to their limited bandwidth, high latency, and significant power consumption. Notably, much of existing improvements in compute performance gains of graphics processing units (GPUs) are based on non-FET scaling improvements. Thus, there is a need to facilitate additional AI and HPC gains by improving chip packaging, architecture, and three-dimensional heterogenous integration of electronic and photonic chips alike.

### BRIEF SUMMARY

Various embodiments of the present disclosure provide a photonic-electronic system-in-package (SiP) network-on-chip (NoC) communication platform that comprises optical through-silicon vias (OTSVs), three-dimensional optical redistribution layers (ORDLs), and three-dimensional heterogeneous integration of photonic and electronic chiplets.

According to some embodiments, a system comprises a plurality of processing cores configured on a chip, wherein a processing core of the plurality of processing cores comprises a plurality of optical transceivers; a plurality of optical through-silicon vias (OTSVs) configured to provide a plurality of vertical optical connections between the plurality of processing cores and a plurality of optical redistribution layers (ORDLs); and the plurality of ORDLs configured to provide a plurality of horizontal optical connections between the plurality of processing cores, wherein (i) the plurality of ORDLs comprises a plurality of layers with non-crossing routings, and (ii) one or more data packets are directed between the plurality of processing cores through the plurality of OTSVs and the plurality of ORDLs.

In some embodiments, an OTSV of the plurality of OTSVs comprises a coupler that is configured to connect one or more horizontal photonic waveguides and one or more vertical photonic waveguides. In some embodiments, the coupler comprises a nano-mirror coupler. In some embodiments, the one or more horizontal photonic waveguides comprise an in-plane waveguide, and the one or more vertical photonic waveguides comprise an out-plane waveguide. In some embodiments, the out-plane waveguide or the in-plane waveguide comprises silicon, silicon nitride, or glass. In some embodiments, the system further comprises a stitched structure that couples the one or more horizontal photonic waveguides to the plurality of OTSVs and the one or more vertical photonic waveguides. In some embodiments, the plurality of OTSVs is configured throughout an interior of the chip, and the plurality of OTSVs comprises a pitch of less than approximately 3µm. In some embodiments, the plurality of ORDLs provides direct, parallel optical connections between two processing cores of the plurality of processing cores. In some embodiments, a quantity of the plurality of ORDLs and an arrangement of the plurality of ORDLs are configurable based on a specific application or a performance criterion associated with passive link loss and number of layers.

According to some embodiments, a method comprises determining, by a computing system, a route for a data packet from a source processing core of a plurality of processing cores to a destination processing core of the plurality of processing cores, wherein (i) the route passes through a plurality of optical through-silicon vias (OTSVs) and a plurality of optical redistribution layers (ORDLs), and (ii) determining the route comprises (a) minimizing a quantity of the plurality of ORDLs, (b) minimizing a quantity of the plurality of OTSVs, (c) optimizing signal loss and layer count by balancing the quantity of the plurality of ORDLs with the quantity of the plurality of OTSVs, and (d) minimizing a quantity of crossing conflicts by dispersing one or more connections from a same processing core of the plurality of processing cores.

In some embodiments, minimizing the quantity of the plurality of ORDLs comprises determining a minimum number of the plurality of ORDLs; and assigning the one or more connections to the minimum number of the plurality of ORDLs. In some embodiments, minimizing the quantity of the plurality of OTSVs comprises routing, using the plurality of OTSVs, a plurality of upper layer connections; and bringing at least a portion of the plurality of upper layer connections down to one or more lower layers of the plurality of ORDLs. In some embodiments, balancing the quantity of the plurality of ORDLs with the quantity of the plurality of OTSVs comprises determining a balance between a ORDL count of usage corresponding to the plurality of ORDLs and the plurality of OTSVs while using one or more ORDLs of the plurality of ORDLs within a defined range. In some embodiments, the method further comprises optimizing the route based on network congestion, link availability, or energy efficiency.

According to some embodiments, a method comprises generating, by a computing system, a system architecture comprising a plurality of processing cores that is configured in a grid layout, wherein a processing core of the plurality of processing cores (i) comprises one or more input and output ports and (ii) is uniformly spaced from other processing cores of the plurality of processing cores within the grid layout; generating, by the computing system, a routing scheme for the system architecture, wherein the routing scheme (i) uses one or more horizontal and vertical segments, (ii) employs one or more routing styles with H-shaped or V-shaped paths, and (iii) minimizes a number of turns and path length; generating, by the computing system, a verified and optimized routing scheme by verifying and optimizing the routing scheme; and generating, by the computing system, a visualization output that corresponds the verified and optimized routing scheme.

In some embodiments, verifying and optimizing the routing scheme comprises determining whether connectivity between the plurality of processing cores is complete; determining an absence of illegal crossings or overlaps; and ensuring minimum spacing criteria. In some embodiments, the method further comprises identifying one or more source or destination ports; generating a plurality of candidate paths; and determining an optimal path from the plurality of candidate paths based on shortest distance, minimum number of layer changes, or overlap avoidance. In some embodiments, determining the optimal path based on overlap avoidance comprises maintaining minimum distance between routes; generating separate layers for horizontal and vertical segments; and placing one or more vias at layer transitions. In some embodiments, the visualization output comprises a main network plot that comprises a system visualization, color-coded routes and processing cores, and/or physical dimensions and scale; and an analysis tool that provides individual core route visualization, one or more route statistics and metrics, and export of route coordinates. In some embodiments, the visualization output comprises a grid-based routing structure with a plurality of horizontal and vertical routing paths that are represented by lines of one or more colors that correspond to one or more routing layers or signal paths, and one or more port locations.

### BRIEF DESCRIPTION OF THE DRAWINGS

Embodiments incorporating teachings of the present disclosure are shown and described with respect to the figures presented herein.

FIG. 1 depicts a diagram of an example chip package in accordance with some embodiments of the present disclosure.

FIG. 2 depicts a schematic diagram of a C2C NoC architecture in accordance with some embodiments of the present disclosure.

FIG. 3 depicts a schematic diagram of example components of a C2C NoC architecture in accordance with some embodiments of the present disclosure.

FIGS. 4A and 4B depict graphs of example passive link loss performance against optical layers in accordance with some embodiments of the present disclosure.

FIG. 5 is flowchart of an example process for routing data packets through an optimal path from a source core to a destination core in accordance with some embodiments of the present disclosure.

FIG. 6 is an example visualization output in accordance with some embodiments of the present disclosure.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Example Technical Improvements

The present disclosure provides a heterogeneous in-package photonic-electronic communication platform. As described above, there are many technical challenges and difficulties associated with traditional electrical interconnects. To overcome such deficiencies, the disclosed heterogeneous in-package photonic-electronic communication platform facilitates improved data communication bandwidth between communication points, such as processing cores, within a chip package. In some embodiments, the in-package photonic-electronic communication platform provides photonic-electronic system-in-package (SiP) network-on-chip (NoC) communication with improved data input/output (I/O) density using optical through-silicon vias (OTSVs), a three-dimensional optical redistribution layer (ORDL), and three-dimensional heterogeneous integration of photonic and electronic chiplets. In some embodiments, the heterogeneous in-package photonic-electronic communication platform enables artificial intelligence (AI) and high-performance computing (HPC) architectures via seamless in-package communication across SiP with various wafer form factors (e.g., 300 mm and beyond, such as 550mm panels).

In some embodiments, the heterogeneous in-package photonic-electronic communication platform allows off-package I/O to enable a ubiquitous communication between stacked wafers or panels, thereby supporting SiP NoC connectivity with minimal physical channels via parallelized optical lanes. In some embodiments, OTSVs are used in conjunction with ORDLs to create a three-dimensional optical interconnect network. OTSVs may provide significant advantages over traditional edge couplers and grating couplers, such as enabling a more compact and dense distribution of optical interconnects, with a pitch, such as of less than approximately 3µm. Unlike edge couplers, which are limited to the periphery, OTSVs may be placed throughout the interior of a chip, maximizing interconnect density and flexibility. In some embodiments, ORDLs enable direct, parallel optical connections between any two cores on a chip, eliminating a need for serialization and deserialization. Furthermore, a routing algorithm is disclosed for dynamically managing data traffic and ensuring efficient communication across a network.

The disclosed heterogeneous in-package photonic-electronic communication platform may provide improved communication performance and enable multi-core HPC/AI architectures with all-to-all core2core (C2C) communication at 100Tbps per core I/O, or 6.4Pbps I/O for an example 8x8 cores configuration on a single 300mm wafer platform. Various embodiments of the present disclosure may enable seamless vertical through-line from development, chip manufacturing scaling partners to product customer, providing a continuous supply chain of advanced packaging ecosystem. Various embodiments of the present disclosure may also change computing architectures by moving the data path out of printed circuit board assembly and into silicon.

### Example System Architecture

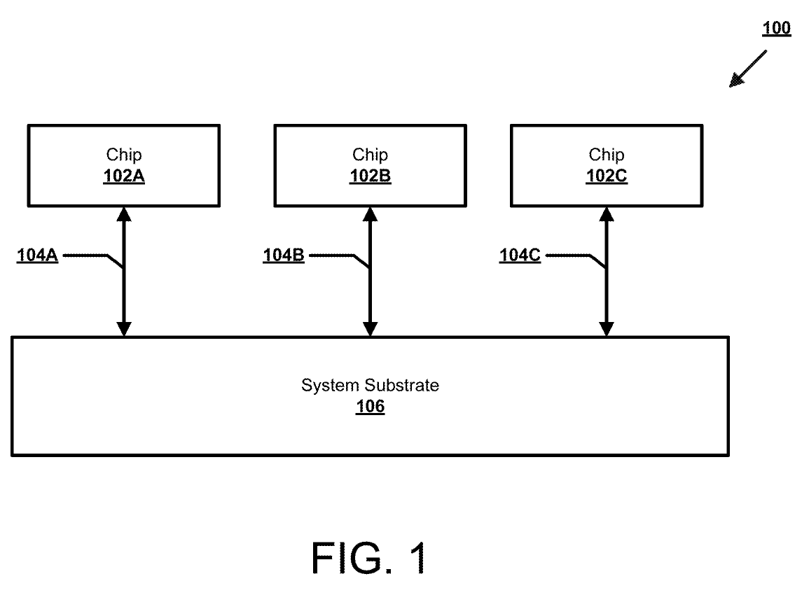

FIG. 1 depicts a diagram of an example chip package 100 in accordance with some embodiments of the present disclosure. The chip package 100 comprises a plurality of chips 102A-102C that are communicatively coupled to a system substrate 106. An individual chip of the plurality of chips 102A-102C may comprise one or more integrated circuit components, such as processing cores (e.g., microprocessors, multi-core processors, arithmetic logic units (ALUs) (e.g., which may be part of one or more graphics processing units (GPUs), tensor processing units (TPUs), and/or the like), memory, I/O driver, signal processing units, and/or photonic integrated circuit components. The plurality of chips 102A-102C are communicatively coupled to the system substrate 106 via communication interfaces 104A-104C. The communication interfaces 104A-104C may comprise a C2C NoC architecture 104A-104C that is all-to-all and non-blocking, which is described in further detail hereforth.

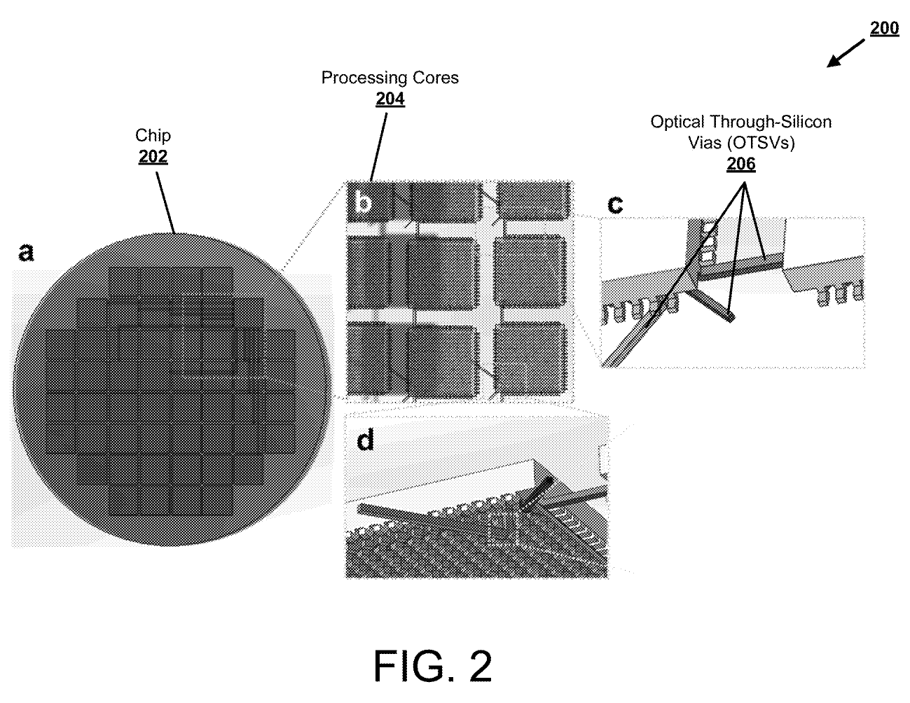

FIG. 2 depicts a schematic diagram of a C2C NoC architecture 200 in accordance with some embodiments of the present disclosure. Processing cores 204 are configured on a chip 202 in accordance with the C2C NoC architecture 200. The processing cores 204 are communicatively coupled to each other with OTSVs 206.

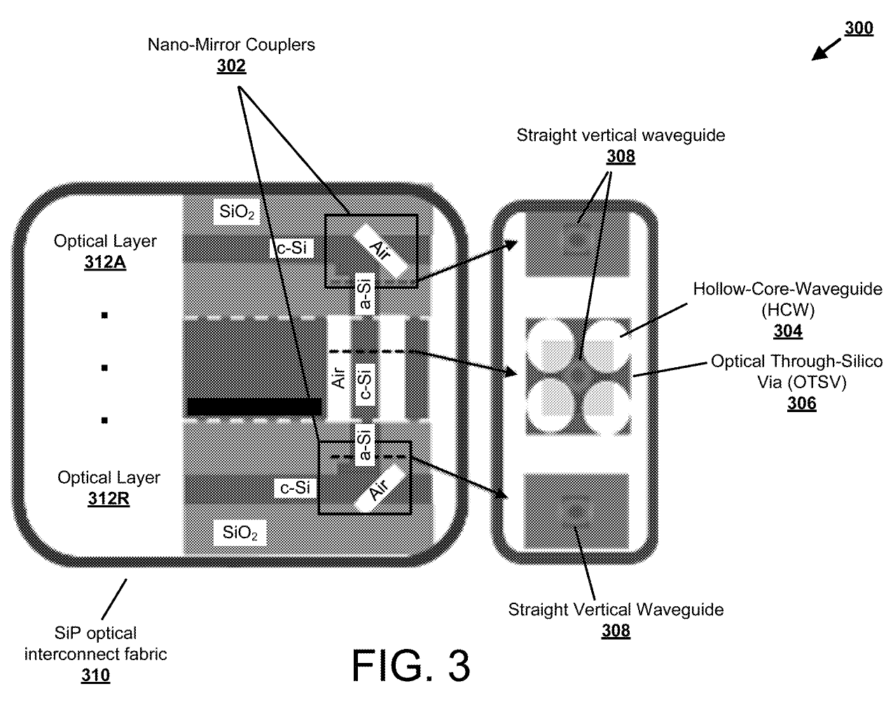

FIG. 3 depicts a schematic diagram of example components 300 of a C2C NoC architecture in accordance with some embodiments of the present disclosure. Example components 300 of a C2C NoC architecture comprise a SiP optical interconnect fabric 310 that connect horizontal photonic waveguides and vertical photonic waveguides. The SiP optical interconnect fabric 310 comprises a plurality of optical layers 312A-312R that provide a plurality of nano-mirror couplers 302. The plurality of nano-mirror couplers 302 may comprise a low-loss, high-compact coupler that efficiently couples horizontal waveguides to vertical waveguides. To achieve efficient coupling between horizontal and vertical waveguides, crystalline silicon (c-Si), amorphous silicon (a-Si), and/or silicon oxide (SiO₂) or silicon nitride (SiNx) waveguides are integrated with the plurality of nano-mirror couplers 302. Thus, the design of the plurality of nano-mirror couplers 302 may be optimized to enhance coupling efficiency, reduce device footprint, and support broadband operation for wavelength-division multiplexing (WDM) applications.

The C2C NoC architecture further comprises OTSV 306, which are configured throughout the interior of a chip (e.g., of the plurality of chips 102A-102C), maximizing interconnect density and flexibility. OTSV 306 is configured with one or more straight vertical waveguides 308 that may be used to connect one or more processing cores to ORDLs via the plurality of nano-mirror couplers 302. The ORDLs may comprise horizontal optical layers that form a 3D photonic routing fabric for facilitating communication between different processing cores with crossing routing paths on a same layer.

The OTSV 306 is further configured with a hollow-core-waveguide (HCW) 304 of a plurality of HCWs that comprises a low-loss, high-compact vertical waveguide for efficient vertical signal propagation. The HCW 304 may comprise hollow core geometries and large air core designs that are capable of achieving insertion losses as low as approximately 1.3 dB/mm while reducing crosstalk to approximately below -20 dB, even in densely packed interconnects. The HCW 304 may be equipped with an optical transceiver that is configured to send and receive optical signals through the OTSV 306. Accordingly, the disclosed C2C NoC architecture may provide a direct, non-blocking connection between processing cores, maximizing data transfer efficiency and minimizing signal loss and latency.

In some embodiments, a three-dimensional photonic in-chip package routing platform comprises a plurality of processing cores, each equipped with optical transceivers; a plurality of OTSV that comprise vertical optical connections (e.g., NMCs) between the processing cores and one or more ORDLs that provide horizontal-to-vertical coupling; and one or more ORDLs that comprise horizontal optical connections that form a 3D photonic routing fabric designed to prevent crossing of routing paths on a same layer (e.g., to minimize the number of horizontal optical layers and eliminate potential crossing conflicts, vertical waveguides, such as HCWs, may be used for routing signals between layers). In some embodiments, a routing algorithm is used to determine optimal data packet paths, thereby reducing a number of layers and OTSVs while maximizing efficiency. That is, the routing algorithm may dynamically optimize communication paths, improving overall system performance and energy efficiency.

In some embodiments, a three-dimensional photonic in-chip package routing platform comprises a plurality of processing cores that are configured on a chip, wherein a processing core of the plurality of processing cores comprises a plurality of optical transceivers; a plurality of OTSVs that are configured to provide a plurality of respective vertical optical connections between the plurality of processing cores and a plurality of ORDLs; the plurality of ORDLs that are configured to provide a plurality of horizontal optical connections between the processing cores; and wherein a routing algorithm is configured to direct one or more data packets between the processing cores through the plurality of OTSVs and the plurality of ORDLs.

In some embodiments, a quantity of the plurality of ORDLs and their arrangement are customized based on a specific application or a performance criterion associated with passive link loss and number of layers.

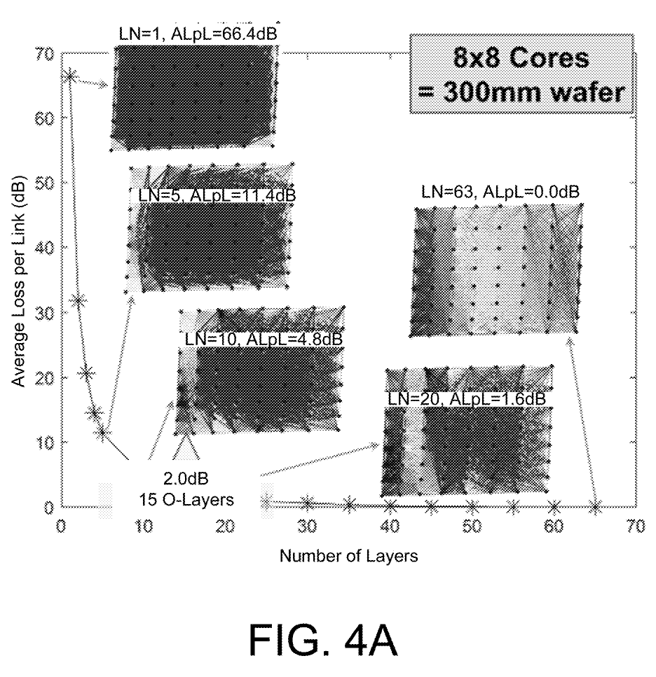

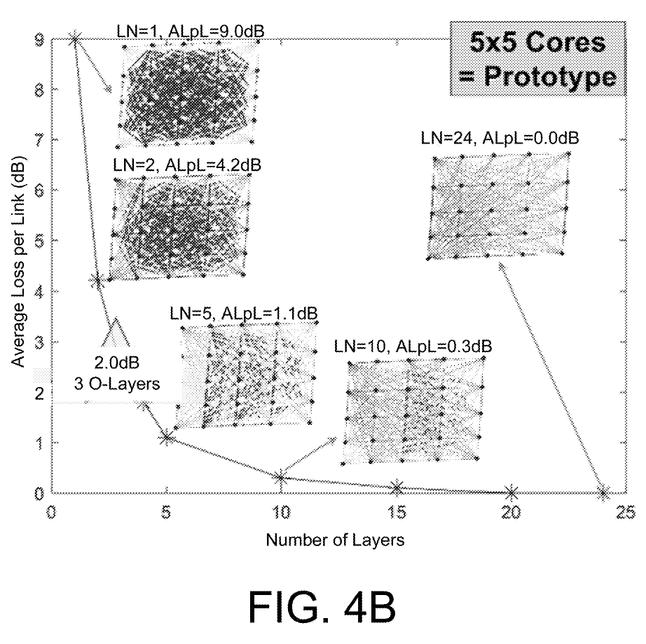

FIGS. 4A and 4B depict graphs of example passive link loss performance against optical layers in accordance with some embodiments of the present disclosure. Similar to metal M-layers, in-package optical layers provide a SiP optical interconnect fabric. As an example, FIG. 4A depicts that 15 optical layers may be designed for a non-blocking NoC at 2.0dB loss penalty for a 300mm SiP platform (e.g., 8x8 processing core die-sized cores) while FIG. 4B depicts that 3 optical layers may be designed for a 5x5 core design (using OTSV).

In some embodiments, one or more of the plurality of OTSVs comprises a coupler that is configured to connect one or more horizontal photonic waveguides and one or more vertical photonic waveguides. In some embodiments, the coupler comprises a nano-mirror coupler. In some embodiments, the one or more horizontal photonic waveguides comprises an in-plane waveguide, wherein the in-plane waveguide comprises, for example, silicon, silicon nitride, or glass. In some embodiments, the one or more vertical photonic waveguides comprises an out-plane waveguide, wherein the out-plane waveguide comprises, for example, silicon, silicon nitride, or glass.

In some embodiments, the three-dimensional photonic in-chip package routing platform further comprises a stitched structure that couples the one or more horizontal photonic waveguides to the plurality of OTSVs and the one or more vertical photonic waveguides. In some embodiments, the plurality of OTSVs comprises a three-dimensional ORDL structure. In some embodiments, the three-dimensional ORDL structure comprises a three-dimensional photonic routing fabric, wherein the three-dimensional photonic routing fabric comprises a plurality of non-crossing routings on a same layer. In some embodiments, the three-dimensional photonic in-chip package routing platform comprises an all-to-all non-blocking C2C NoC architecture.

### Example System Operations

Various embodiments of the present disclosure describe steps, operations, processes, methods, functions, and/or the like for routing data packets in a three-dimensional photonic in-chip package routing platform.

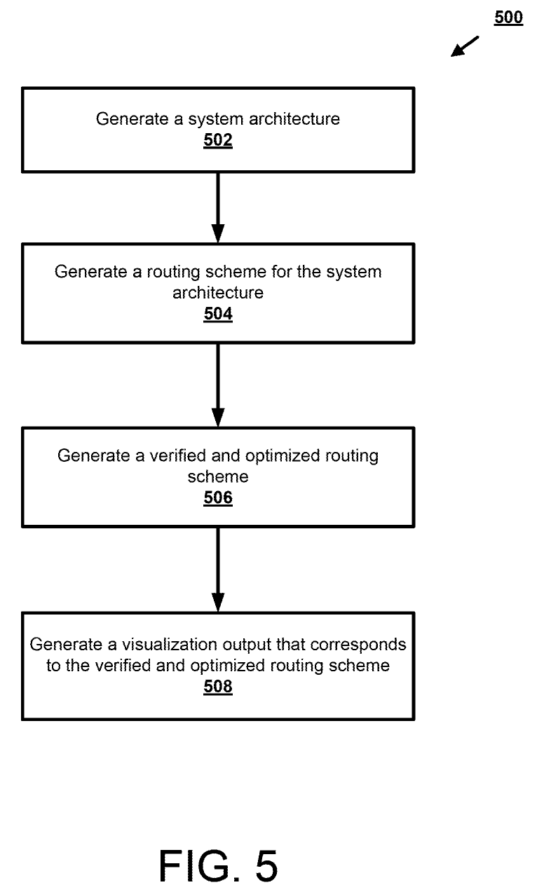

FIG. 5 is flowchart of an example process 500 for routing data packets through an optimal path from a source processing core to a destination processing core in accordance with some embodiments of the present disclosure. The flowchart diagram depicts an algorithm for optimal data packet paths, reducing the number of layers and OTSVs while maximizing efficiency. The process 500 may be implemented by one or more computing devices, entities, and/or systems described herein. For example, via the various steps/operations of the process 500, a computing system may determine a direct, non-blocking connection between processing cores, maximizing data transfer efficiency and minimizing signal loss and latency. By doing so, the process 500 may dynamically optimize communication paths, thereby improving overall system performance and energy efficiency.

In some embodiments, the process 500 begins at step/operation 502 when a computing system generates a system architecture. Determining the system architecture may comprise configuring a plurality of processing cores in a grid layout. Each of the processing cores may comprise one or more input and/or output ports and may be uniformly spaced from other processing cores within the grid layout. In some embodiments, determining the system architecture further comprises determining top and bottom high bandwidth memory (HBM) placement for each processing core, dedicating space for memory access, or optimizing the system architecture for minimal interference.

In some embodiments, at step/operation 504, the computing system generates a routing scheme for the system architecture. For example, the routing scheme may comprise a Manhattan routing strategy that uses horizontal and vertical segments, employs routing styles including H-shaped and V-shaped paths, and minimizes the number of turns and path length. In some embodiments, executing the routing scheme further comprises identifying source and destination ports, generating a plurality of candidate paths, and determining an optimal path from the plurality of candidate paths based on shortest distance, minimum number of layer changes, and/or overlap avoidance. In some embodiments, determining an optimal path based on overlap avoidance comprises maintaining minimum distance between routes, generating separate ORDLs for horizontal and vertical segments, and/or placing vias at layer transitions.

In some embodiments, at step/operation 506, the computing system generates a verified and optimized routing scheme by verifying and optimizing the routing scheme. Verifying the routing scheme may comprise determining whether connectivity between all processing cores are complete, determining whether there are no illegal crossings or overlaps, and/or ensuring minimum spacing criteria. Optimizing the routing scheme may comprise evaluating the routing scheme based on one or more performance metrics, such as total number of successful routes, failed connection identification, and/or overlap detection in horizontal and vertical segment layers. Additionally, and/or alternatively, the routing scheme may be optimized based on factors, such as network congestion, link availability, and energy efficiency, by minimizing layer and via quantities. In some embodiments, routing decisions are dynamically adjusted to ensure balanced data traffic distribution and prevent bottlenecks.

In some embodiments, routing an optimal path comprises determining a minimum layer count to reduce a quantity of ORDLs; determining a minimum via to reduce a quantity of OTSVs; balancing OTSVs and ORDLs to optimize signal loss and layer count; and generating lateral separation to minimize crossing conflicts. In some embodiments, determining the minimum layer count comprises determining a theoretical minimum number of ORDLs needed; and assigning connections to layers efficiently to reduce total ORDLs used. In some embodiments, determining the minimum via comprises using OTSVs to route a plurality of connections on upper layers; and bringing at least a portion of the plurality of connections down to lower layers thereby decreasing a quantity of ORDLs. In some embodiments, balancing OTSVs and ORDLs comprises determining a balance between ORDL count and OTSV usage to keep signal loss low while using a sufficient (e.g., within a defined range) number of ORDLs. In some embodiments, generating the lateral separation comprises dispersing connections from a same processing core to reduce crossing conflicts and facilitate routing while balancing ORDL and OTSV usage.

In some embodiments, routing an optimal path comprises receiving a data packet at a source core of a plurality of processing cores. The source core may receive the data packet from an application, a memory controller, or another processing element within a chip package. Upon receiving the data packet, a destination core may be determined to which the data packet is to be transmitted.

In some embodiments, routing the optimal path further comprises determining a route for the data packet from the source core to the destination core. The route may pass through a plurality of OTSVs and a plurality of ORDLs. Determining the route may comprise evaluating multiple candidate paths and selecting an optimal path based on one or more optimization criteria. Routing the optimal path may further comprise forwarding the data packet to the destination core along the determined route, wherein the data packet traverses the plurality of OTSVs for vertical signal propagation and the plurality of ORDLs for horizontal signal propagation.

In some embodiments, determining the route comprises applying one or more optimization criteria. The one or more optimization criteria may comprise minimizing a quantity of ORDLs, minimizing a quantity of OTSVs, balancing the quantity of ORDLs with the quantity of OTSVs to optimize signal loss and layer count, or minimizing crossing conflicts by dispersing connections from a same processing core. Such optimization criteria may be applied individually or in combination to achieve efficient routing with reduced signal loss and improved system performance.

In some embodiments, minimizing the quantity of ORDLs comprises determining a theoretical minimum number of layers. The theoretical minimum number of layers may be determined based on the number of processing cores, connectivity requirements, or physical constraints of the chip package. Minimizing the quantity of ORDLs may further comprise assigning connections to ORDLs efficiently to reduce total ORDLs used. Efficient ORDL assignment may comprise grouping connections that do not cross each other on a same ORDL and distributing connections across ORDLs to balance utilization.

In some embodiments, minimizing the quantity of OTSVs comprises using OTSVs to route a plurality of connections on upper layers of the ORDLs. The upper layers may be used for longer-distance connections or connections that would otherwise cause crossing conflicts on lower layers. Minimizing the quantity of OTSVs may further comprise bringing at least a portion of the plurality of connections down to lower layers of the plurality of ORDLs, thereby decreasing a quantity of ORDLs called for. By doing so, vertical routing through OTSVs may be leveraged to reduce the overall number of horizontal layers needed while maintaining non-blocking connectivity.

In some embodiments, balancing the quantity of ORDLs with the quantity of OTSVs comprises determining a balance between ORDL count and OTSV usage to keep signal loss low while using a number of ORDL layers within a defined range. The defined range may be determined based on performance requirements, manufacturing constraints, or cost considerations. Balancing ORDL count and OTSV usage may comprise iteratively adjusting the allocation of connections between OTSVs and ORDLs to achieve an optimal trade-off between vertical and horizontal routing resources while maintaining acceptable signal loss levels.

In some embodiments, minimizing crossing conflicts comprises dispersing connections from a same processing core across multiple layers or routing paths. Dispersing connections may reduce the likelihood of routing conflicts and facilitate easier routing while balancing ORDL and OTSV usage. The lateral separation of connections from a same processing core may be achieved by assigning different output ports of the processing core to different routing layers or by staggering the routing paths in the horizontal plane.

In some embodiments, at step/operation 508, the computing system generates a visualization output that corresponds to the verified and optimized routing scheme. The visualization output may comprise a main network plot that provides a complete system visualization, color-coded routes and processing cores, and/or physical dimensions and scale. Additionally, and/or alternatively, the visualization output may comprise analysis tools that provide individual core route visualization, route statistics and metrics, and/or export of route coordinates.

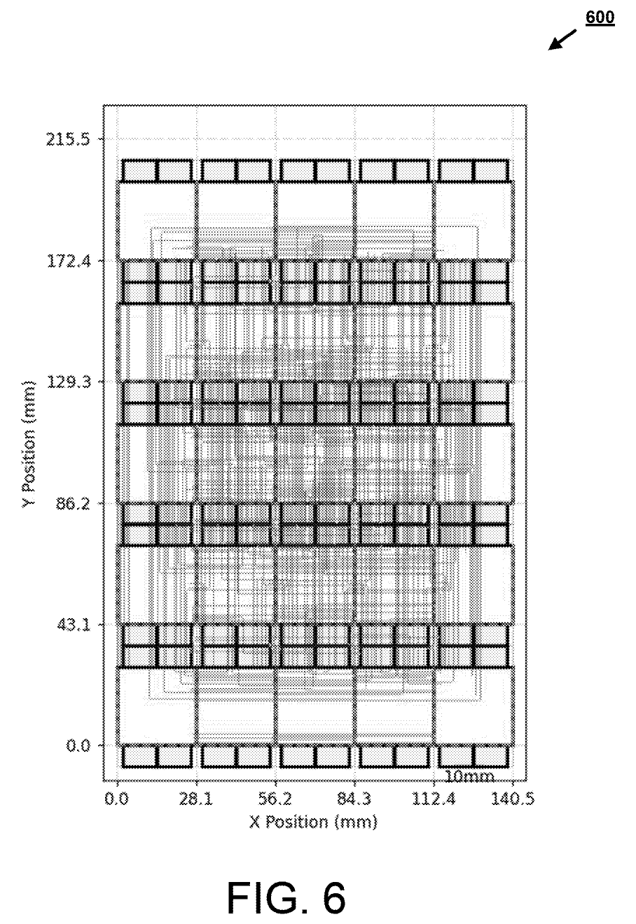

FIG. 6 is an example visualization output 600 in accordance with some embodiments of the present disclosure. The visualization output 600 comprises a 5x5 photonic router layout with grid points and vias. The visualization output 600 is provided with a two-dimensional coordinate system with X position measured in millimeters along a horizontal axis and Y position measured in millimeters along a vertical axis. Port locations or connection points within the routing fabric are distributed throughout the visualization output 600. The routing paths form an interconnected network of horizontal and vertical paths generated based on a verified and optimized routing scheme. In some embodiments, the visualization output is generated by generating N×N grids, port pairs, and candidate horizontal and vertical paths, with design-rule checks applied for overlap, boundaries, and layer assignments, enabling full all-to-all connectivity for grid configurations.

As shown in FIG. 6, routing may avoid using HBMs as waveguide connection points such that waveguide start and end points lie within core regions, which may provide more freedom for path placement and support all-to-all connectivity between cores without overlaps. For example, an unordered pair of cores may receive one optical route such that each core may communicate with every other core. Core positions may be defined by their centers – the distance between two cores may comprise the Euclidean distance between these centers. Core pairs may be enumerated and sorted by center-to-center distance, with shorter distances routed first. By doing so, routing resources may be reserved for short links before longer ones are placed.

By moving all waveguide start and end points inside the cores, a regular grid of ports may be placed across the core area, giving more freedom to choose port pairs and vias such that the routing may achieve full all-to-all connectivity without overlaps. Keeping ports inside the cores may also simplify manufacturability and component design by separating photonic routing from HBM memory-interface regions. That is, HBM regions may comprise constraints on layer stack, thermal management, and pinout for memory stacks and I/O. Bringing photonic waveguide terminations into HBM regions may mix interconnect design with memory-interface design and complicate process integration, mask layout, and placement of other components. As such, keeping waveguide ports inside the core regions may confine photonic routing to the core tiles with a consistent layer and spacing scheme.

In some embodiments, a method for routing data packets in a 3-dimensional photonic in-chip package routing platform comprises determining a route for a data packet from a source processing core to a destination processing core, wherein the route passes through a plurality of OTSVs and ORDLs; receiving a data packet at the source processing core; and forwarding the data packet to the destination processing core along the determined route.

In some embodiments, determining the route comprises minimizing a quantity of ORDLs; minimizing a quantity of OTSVs; balancing the quantity of ORDLs with the quantity of OTSVs to optimize signal loss and layer count; and minimizing crossing conflicts by dispersing connections from a same processing core.

Accordingly, embodiments of the present disclosure provide a transformative solution for AI and HPC platforms, addressing the critical challenges of high-bandwidth, low-latency, and energy-efficient communication.

### Conclusion

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation.

1. A system comprising:
a plurality of processing cores configured on a chip, wherein a processing core of the plurality of processing cores comprises a plurality of optical transceivers;
a plurality of optical through-silicon vias (OTSVs) configured to provide a plurality of vertical optical connections between the plurality of processing cores and a plurality of optical redistribution layers (ORDLs); and
the plurality of ORDLs configured to provide a plurality of horizontal optical connections between the plurality of processing cores, wherein:
(i) the plurality of ORDLs comprises a plurality of layers with non-crossing routings, and
(ii) one or more data packets are directed between the plurality of processing cores through the plurality of OTSVs and the plurality of ORDLs.

2. The system of claim 1, wherein an OTSV of the plurality of OTSVs comprises a coupler that is configured to connect one or more horizontal photonic waveguides and one or more vertical photonic waveguides.

3. The system of claim 2, wherein the coupler comprises a nano-mirror coupler.

4. The system of claim 2, wherein:
(i) the one or more horizontal photonic waveguides comprise an in-plane waveguide, and
(ii) the one or more vertical photonic waveguides comprises an out-plane waveguide.

5. The system of claim 4, wherein the out-plane waveguide or the in-plane waveguide comprises silicon, silicon nitride, or glass.

6. The system of claim 4, further comprising a stitched structure that couples the one or more horizontal photonic waveguides to the plurality of OTSVs and the one or more vertical photonic waveguides.

7. The system of claim 1, wherein:
(i) the plurality of OTSVs is configured throughout an interior of the chip, and
(ii) the plurality of OTSVs comprises a pitch of less than approximately 3µm.

8. The system of claim 1, wherein the plurality of ORDLs provides direct, parallel optical connections between two processing cores of the plurality of processing cores.

9. The system of claim 1, wherein a quantity of the plurality of ORDLs and an arrangement of the plurality of ORDLs are configurable based on a specific application or a performance criterion associated with passive link loss and number of layers.

10. A method comprising:
determining, by a computing system, a route for a data packet from a source processing core of a plurality of processing cores to a destination processing core of the plurality of processing cores, wherein:
(i) the route passes through a plurality of optical through-silicon vias (OTSVs) and a plurality of optical redistribution layers (ORDLs), and
(ii) determining the route comprises:
(a) minimizing a quantity of the plurality of ORDLs,
(b) minimizing a quantity of the plurality of OTSVs,
(c) optimizing signal loss and layer count by balancing the quantity of the plurality of ORDLs with the quantity of the plurality of OTSVs, and
(d) minimizing a quantity of crossing conflicts by dispersing one or more connections from a same processing core of the plurality of processing cores.

11. The method of claim 10, wherein
minimizing the quantity of the plurality of ORDLs comprises:
determining a minimum number of the plurality of ORDLs; and
assigning the one or more connections to the minimum number of the plurality of ORDLs.

12. The method of claim 10, wherein
minimizing the quantity of the plurality of OTSVs comprises:
routing, using the plurality of OTSVs, a plurality of upper layer connections; and
bringing at least a portion of the plurality of upper layer connections down to one or more lower layers of the plurality of ORDLs.

13. The method of claim 10, wherein
balancing the quantity of the plurality of ORDLs with the quantity of the plurality of OTSVs comprises determining a balance between a ORDL count of usage corresponding to the plurality of ORDLs and the plurality of OTSVs while using one or more ORDLs of the plurality of ORDLs within a defined range.

14. The method of claim 10, further comprising:
optimizing the route based on network congestion, link availability, or energy efficiency.

15. A method comprising:
generating, by a computing system, a system architecture comprising a plurality of processing cores that is configured in a grid layout, wherein a processing core of the plurality of processing cores (i) comprises one or more input and output ports and (ii) is uniformly spaced from other processing cores of the plurality of processing cores within the grid layout;
generating, by the computing system, a routing scheme for the system architecture, wherein the routing scheme:
(i) uses one or more horizontal and vertical segments,
(ii) employs one or more routing styles with H-shaped or V-shaped paths, and
(iii) minimizes a number of turns and path length;
generating, by the computing system, a verified and optimized routing scheme by verifying and optimizing the routing scheme; and
generating, by the computing system, a visualization output that corresponds to the verified and optimized routing scheme.

16. The method of claim 15, wherein verifying and optimizing the routing scheme comprises:
determining whether connectivity between the plurality of processing cores is complete;
determining an absence of illegal crossings or overlaps; and
ensuring minimum spacing criteria.

17. The method of claim 15 further comprising:
identifying one or more source or destination ports;
generating a plurality of candidate paths; and
determining an optimal path from the plurality of candidate paths based on shortest distance, minimum number of layer changes, or overlap avoidance.

18. The method of claim 17, wherein determining the optimal path based on overlap avoidance comprises:
maintaining minimum distance between routes;
generating separate layers for horizontal and vertical segments; and
placing one or more vias at layer transitions.

19. The method of claim 15, wherein the visualization output comprises:
a main network plot that comprises a system visualization, color-coded routes and processing cores, and/or physical dimensions and scale; and
an analysis tool that provides individual core route visualization, one or more route statistics and metrics, and export of route coordinates.

20. The method of claim 15, wherein the visualization output comprises a grid-based routing structure with a plurality of horizontal and vertical routing paths that are represented by lines of one or more colors that correspond to one or more routing layers or signal paths, and one or more port locations.
